(19) United States
(12) Patent Application Publication
(10) Pub. No.: US 2026/0038551 A1
(43) Pub. Date: Feb. 5, 2026

(54) MEMORY CIRCUITS WITH WORD LINE OVERDRIVE

(71) Applicant: Taiwan Semiconductor Manufacturing Company, Ltd., Hsinchu (TW)

(72) Inventor: Makoto Yabuuchi, Hsinchu (TW)

(73) Assignee: Taiwan Semiconductor Manufacturing Company, Ltd., Hsinchu (TW)

(21) Appl. No.: 18/795,058

(22) Filed: Aug. 5, 2024

(51) Int. Cl. G11C 8/08; G11C 11/419

(52) U.S. Cl. CPC G11C 8/08; G11C 11/419

(57) ABSTRACT

A memory circuit includes memory cells commonly coupled to a word line, a word line driver, an overvoltage generator, and a memory controller. The word line driver is selectively coupled to the word line to assert the word line to a first voltage. The memory controller can couple the word line driver with the word line to assert the word line to the first voltage. The memory controller can decouple the word line driver from the word line to maintain the word line at the first voltage. The memory controller can couple the overvoltage generator with the capacitor to charge the capacitor to a second voltage. The memory controller can couple the capacitor with the word line to assert the word line to the second voltage. The memory controller can write a data value to a memory cell with the word line driven to the second voltage.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory circuit, in accordance with some embodiments.

FIG. 2 illustrates a set of waveforms of various signals when operating the memory circuit of FIG. 1, in accordance with some embodiments.

FIG. 3 illustrates a schematic diagram of a portion of the memory circuit of FIG. 1, in accordance with some embodiments.

FIG. 4 illustrates a schematic view of voltage line and capacitor electrode, in accordance with some embodiments.

FIG. 5 illustrates a physical implementation of the voltage line and capacitor electrode of FIG. 4, in accordance with some embodiments.

FIG. 6 illustrates another block diagram of a memory circuit, in accordance with some embodiments.

FIG. 7 illustrates a schematic diagram of a portion of the memory circuit of FIG. 6, in accordance with some embodiments.

FIG. 8 illustrates a schematic diagram of a memory circuit 6, in accordance with some embodiments.

FIG. 9 illustrates a block diagram of a portion of a memory circuit, in accordance with some embodiments.

FIG. 10 illustrates a schematic diagram of a portion of the memory circuit of FIG. 9, in accordance with some embodiments.

FIG. 11 illustrates a flow chart of a method for operation of a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Static random-access memory (SRAM) is a type of semiconductor memory typically used in computing applications requiring high-speed data access. For example, cache memory applications use SRAMs to store frequently accessed data, e.g., data accessed by central processing units. The SRAM memory can consume power according to an operation thereof, incident to the lossy charging and discharging of bit lines, word lines, and the like, which are used to select, read, or write memory cells of the SRAM. A write assist circuit can expand operating margin by increasing a voltage, although such an increase can increase total power usage. For example, a write assist circuit can increase margin by lowering an “off” state voltage of a bit line, but such a change can increase power usage in proportion to a length of the bit line (e.g., corresponding to a parasitic capacitance) and a number of inputs or outputs (I/O) coupled with the bit line.

In general, a write assist circuit can overdrive a word line connected to one or more memory cells of a memory cell array. The write assist circuit can include a first driver to drive a selected word line to a first voltage, and then decouple the first driver from the word line to leave the word line floating at the first voltage. The write assist circuit can include a second driver to charge a capacitor to a second voltage which is greater than the first voltage, and couple the capacitor to the (floating) word line to assert the word line to the second voltage. The capacitor may be implemented via metal lines in a metallization layer of a memory device. Some write assist circuits include multiple capacitor electrodes to selectively assert the word line to different voltages exceeding the first voltage. (The separate electrodes may also be referred to as separate capacitors, without limiting effect). The write assist circuit can select a voltage according to an operating condition (e.g., operating voltage or temperature, or selected memory timing). In some embodiments, the write assist circuit can sequence a coupling of multiple capacitor electrodes to slew the voltage of the word line.

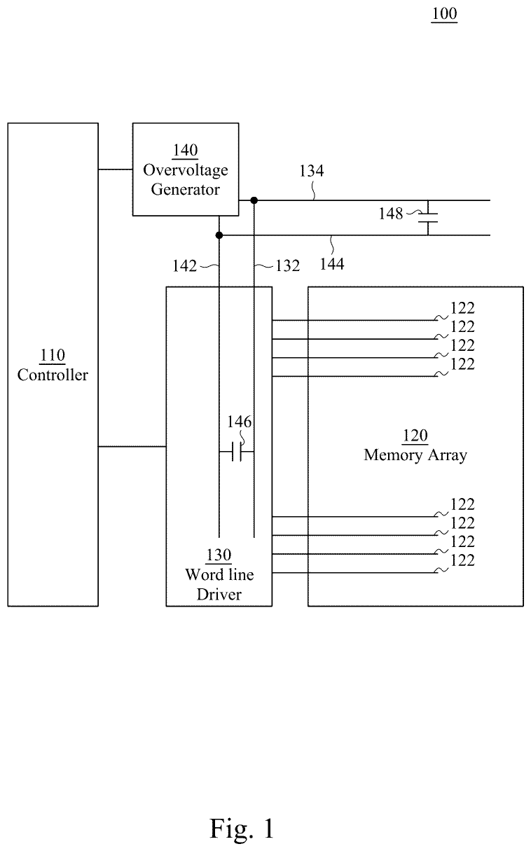

FIG. 1 illustrates a block diagram of a memory system or circuit 100, in accordance with various embodiments. A memory array 120 is a hardware component that stores data. In various embodiments, the memory array 120 is embodied as a semiconductor memory device. The memory array 120 includes a number of storage circuits or memory cells. In some embodiments, the memory array 120 includes word lines 122 (e.g., WL0, WL1 . . . . WLJ), each extending in a first direction and bit lines extending in a second direction (e.g., a second direction perpendicular to the first direction). The word lines 122 and the bit lines may be conductive metals or conductive rails. Each memory cell is connected to one or more corresponding word lines 122 and one or more corresponding bit lines BL, and can be operated according to voltages or currents through the corresponding word line(s) 122 and the corresponding bit line(s). In some embodiments, the memory array 120 includes additional lines (e.g., sense lines, reference lines, reference control lines, power rails, etc.).

A controller 110 can cause the operation of the various lines via one or more line drivers. For example, the controller 110 can control a timing of signal assertion or de-assertion of the various lines to provide signals to the memory cells to cause the memory cells to store information or transmit previously stored information. In some instances, the controller 110 can operate according to multiple timing parameters such as setup times, hold times, recovery times, access times, and so forth. For example, longer times may correspond to low power or high temperature operation and shorter times may correspond to higher power or high temperature operation. The controller 110 can determine the timing parameters locally, or receive timing parameters according to a communication with a further controller, such as via a register or other communicative coupling. For example, the timing parameter can include a configurable setting accessible to the controller 110 via a timing register and writable to the register via a second controller (e.g., another controller in communication with the memory controller 110).

The lines of the memory array 120 are driven by a line driver. For example, a word line driver 130 can selectively couple with a selected word line 122 to assert the selected word line 122 to an operational voltage (e.g., to effect a read or write operation). A second line driver can assert the word line 122 to a second operational voltage. The second line driver may operate at voltages exceeding a voltage of the word line driver, and may be referred to as an overvoltage generator (OVG) 140. The overvoltage generator can charge a capacitor to the second operational voltage and couple the capacitor with the word line 122. The second operational voltage can increase a voltage operating margin of the various memory cells of the memory array 120. An operating margin of the memory cells can vary according to an operating voltage (e.g., during a sleep state), high operating frequencies/low latency, or high temperatures, such that the margin between a voltage to successfully conduct a read or write operation may compress, or become negative, leading to memory errors.

The word line driver 130 can assert a positive voltage, VDD, for the word lines 122. For example, the word line driver 130 can assert a first VDDHD line 132, disposed perpendicularly to the word lines 122, and a second VDDHD line 134 disposed parallel to the word lines 122. The various VDDHD lines are so named to emphasize that they are not limited to receiving a VDD voltage. Although VDDHD lines may sometimes be referred to as VDD header lines or VDD high drain lines, such backronyms are should not be construed to limit the present disclosure. The combination of the first VDDHD line 132 and the second VDDHD line 134 can increase a linear distance along the VDDHD lines. Accordingly, a capacitor electrode, depicted as including a first electrode portion 142 and a second electrode portion 144 corresponding to the first VDDHD line 132 and the second VDDHD line 134, can increase a capacitance as proportional to the linear distance (to a first order of approximation, as details of a layout can modulate the realized capacitance). That is, a first capacitance 146 is formed between the first VDDHD line 132 and the first electrode portion 142 and a second capacitance 148 is formed between the second VDDHD line 134 and the second electrode portion 144. The one or more lines or other portions of the electrode of the capacitor can be referred to generally as an electrode 142. The one or more lines or other portions of a conductive structure to can be referred to generally as VDDHD 132, or a VDDHD structure 132.

The controller 110 can cause the activation of the OVG 140 to avoid memory errors. In some embodiments, the controller 110 can activate the OVG 140 for all writes, or all assertions of the word line 122. In some embodiments, the controller 110 can activate the OVG 140 based on an operating condition. For example, the controller 110 can couple with a diode or other thermal sensor to receive an indication of an operating temperature of a semiconductor die including the memory array 120 and activate the OVG 140 based on the temperature. Further, the controller 110 can activate the OVG 140 based on a timing parameter, or a voltage. The voltage can correspond to a sensed voltage or a nominal commanded operating voltage, such as an active or sleep state voltage.

In some embodiments, the OVG 140 can include more than one driver to assert the word line 122. For example, each of a first, second, and third driver can assert the word line 122 to different voltages. The first, second, and third driver can include distinct drivers, or share one or more components. Put differently, the OVG 140 may include a selectable output voltage. The controller 110 can select an output voltage of the OVG 140 according to an operating condition or a predefined slew rate (e.g., can sequence two or more of the output voltages). The OVG 140 can charge different capacitor electrodes to different values.

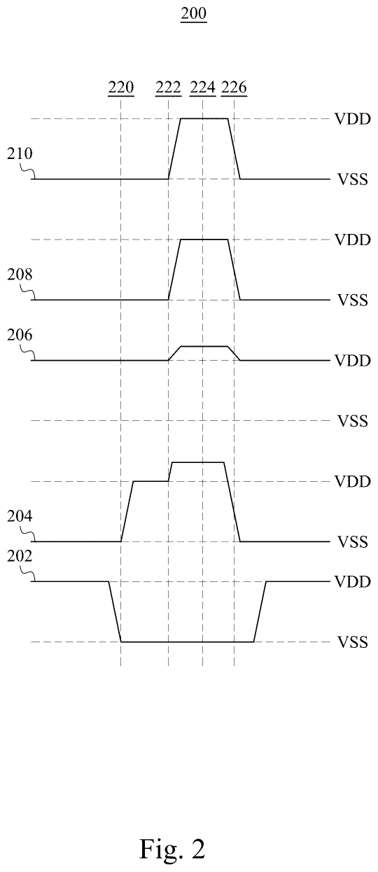

FIG. 2 illustrates a set of waveforms 200 of various signals when operating the memory circuit 100 of FIG. 1, in accordance with some embodiments. A first waveform 202 corresponds to a selection of a bit line. For example, the bit line is selected according to an active low selection in the depiction to write a low value (e.g., corresponding to a logical zero). Although depicted as extending to a ground reference, VSS, some embodiments may additionally underdrive the bit line to realize increased margin. However, such operation may substantially increase power use, as indicative above. Accordingly, in various embodiments, the overdriving word line 122 is overdriven to the exclusion of under-driving the bit line (or the overdriving and under-driving are used in combination in limited circumstances, such as extremely tight timing or high temperatures).

A second waveform 204 corresponds to a selection of a word line 122. A third waveform 206 corresponds to an overdriving of a VDDHD line 132, 134. A fourth waveform 208 corresponds to a charging of a capacitor electrode 144, 146. A fifth waveform 210 corresponds to an assist enable line (ASTE) of an assist circuit (such as the OVG 140 of FIG. 1), as received from the memory controller 110. The actuation of the various signals depicted according to the set of waveforms 200 can include various offsets, slew rates, or other implementation details to aid in deterministic operation (e.g., to avoid race conditions). References to a time of the signals is not intended to limit the transmission or arrival of such signals to an exact same time. Indeed, a layout, drive strength, or other aspects of a design of the memory circuit 100 may be implemented to avoid such a condition. Instead, the times provided herein are abstracted as may be useful in understanding the present disclosure.

At a first time 220, the word line 122 and bit line are asserted (e.g., the word line 122 is driven to an active high state and the bit line is driven to a state of a written bit). Upon the assertion of the word line 122 and bit line, a word line driver 130 can decouple from the word line 122 such that the word line 122, as coupled with the VDDHD line 132, 134 becomes a floating node. In some instances, such a decoupling may be performed immediately prior to the second time, to reduce leakage from the floating node.

At a second time 222, a capacitor electrode may be charged to a level exceeding VDD. For example, the OVG 140 can include a charge pump or other circuit to generate the greater voltage, or the OVG 140 can generate a voltage with respect to another ground reference to realize the higher voltage. The charging of the capacitor electrode 144, 146, (depicted according to fourth waveform 208) can cause an increase in the VDDHD 132, 134 lines in excess of the VDD voltage as depicted according to the third waveform 206. This voltage can, in turn, overdrive the second waveform 204. The overvoltage can increase an operating voltage margin of various memory cells coupled with the word line 122. A voltage of the word line 122 as measured at a memory cell can be different (e.g., less than) depicted according to the second waveform 204. For example, according to resistive or other losses, the word line voltage as measured at a cell may be equal to or below VDD, even where the word line voltage proximal to a driver therefor exceeds VDD.

At a third time 224 (e.g., with the word line 122 driven to a voltage exceeding VDD), the controller 110 can write a data value to, or read a data value from, a memory cell. At a fourth time 226 the various signal assertions can be de-asserted to return to the memory circuit 100 to a state prior to the first time 220, excepting the stored data or retrieved data value.

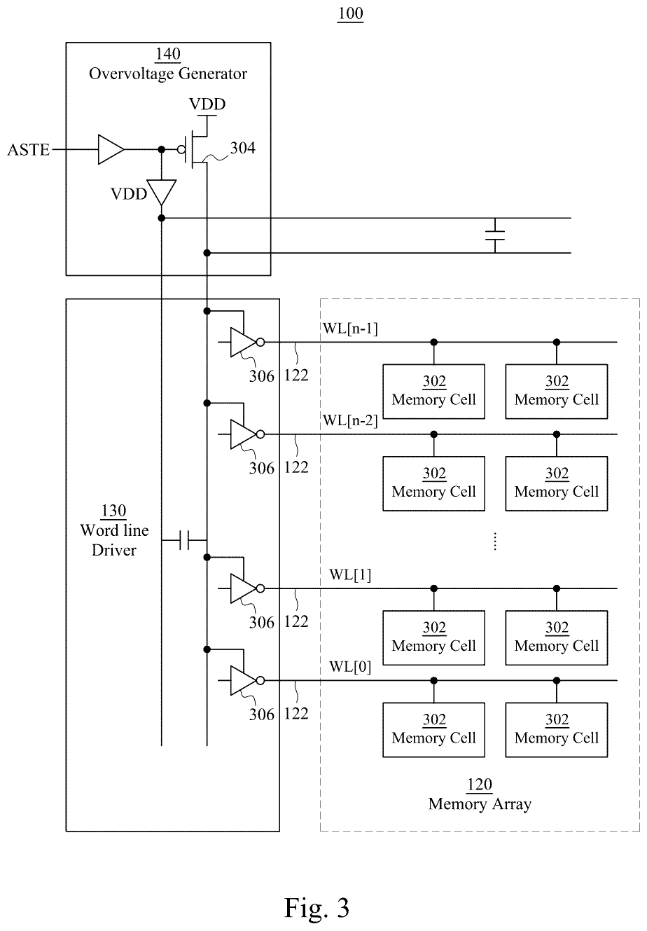

FIG. 3 illustrates a schematic diagram of a portion of the memory circuit 100 of FIG. 1, in accordance with some embodiments. Referring to the memory array 120, the array includes a row of memory cells 302 (e.g., bitcells). Each word line 122 connects with multiple memory cells 302, such as tens or hundreds of memory cells 302. Each memory cell 302 may be a Static Random-Access Memory (SRAM) cell. For example, the memory cell 302 can be implemented as a six-transistor (6T) or eight-transistor (8T) SRAM cell. However, it should be understood that the memory cell 302 can be implemented in any of various other memory configurations (e.g., DRAM), while remaining within the scope of the present disclosure.

Referring to the OVG 140, a transistor 304 couples the VDDHD lines 132 to a VDD voltage. The gate of the transistor 304 is coupled with a control signal from a memory controller 110 (ASTE). The gate further connects to a capacitor so that the ASTE signal can store charge on the capacitor. Each word line 122 may be selectable via a selection input 306 so that the VDD line 132 only couples with memory cells 302 of a selected word line 122.

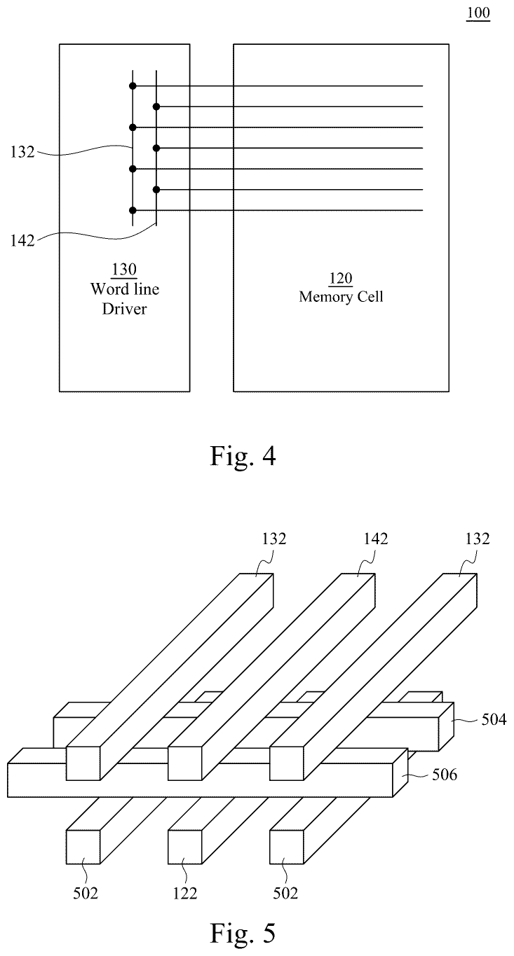

Referring now to FIGS. 4 and 5, voltage lines and capacitor electrodes are depicted according to schematic and perspective views, respectively. Particularly, FIG. 4 illustrates a schematic view of a voltage line, VDDHD 132 and capacitor electrodes 142, in accordance with some embodiments. FIG. 5 illustrates a physical implementation of the voltage line and capacitor electrode of FIG. 4, in accordance with some embodiments.

A VDDHD structure 132 extends, in one or more directions, parallel to the capacitor electrode 142. The VDDHD structure 132 includes a first portion (e.g., a first VDDHD line 132 depicted as constituent to or disposed over the word line driver 130.) For example, the VDDHD structure 132 can be disposed in a metallization layer over an active surface of the memory circuit 100. Particularly, the VDDHD structure 132 includes a first VDDHD line 132 over the word line driver 130, which is vertically spaced from an active surface (e.g., transistors) of the word line driver 130. The VDDHD structure 132 includes a second VDDHD line 134 over the memory array 120, which is vertically spaced from an active surface (e.g., transistors) of a memory cell 302 of the memory array 120. The vertical spacing refers to a direction perpendicular to a planar or substantially planar surface of a semiconductor device including the active surface (e.g., upward from the active surface into metallization layers formed over a semiconductor die). In some embodiments, a lateral spacing may further be present, so that the various lines extend over the transistor with a lateral offset. Similarly, the capacitor includes a metal line disposed in a metallization layer of the memory circuit 100. For example, the capacitor electrode 142 includes a portion (e.g., a second electrode portion 144) disposed parallel to a line of the VDDHD structure 132 (e.g., the second VDDHD line 134).

As is depicted in FIG. 5, the VDDHD structure 132 and the capacitor electrode 142 can include lines disposed in a same metallization layer extending parallel to each other so as to increase a capacitance therebetween. For example, the lines can include the first VDDHD line 132 and the first capacitor electrode portion 142, or the second VDDHD line 134 and the second capacitor electrode portion 144. In some embodiments, the VDDHD structure 132 and the capacitor electrode 142 can include lines in adjacent layers of the metallization layers which extend in parallel to achieve a total capacitance. Moreover, the VDDHD structure 132 and the capacitor electrode 142 can extend in various directions (e.g., perpendicular directions) to increase a linear extension corelating to increased capacitance.

With continued reference to FIG. 5, the word line 122 or a reference voltage line 502, VSS, may be disposed in a different metallization layer from lines of the VDDHD structure 132 and the capacitor electrode 142, which may aid in signal isolation therebetween. For example, a power line 504 or other signal line 506 can separate the lines of the VDDHD structure 132 and the capacitor electrode 142 from the word line 122 or VSS line 502. In some embodiments, the power line 504 or other signal line 506 can include lines extending substantially perpendicular to lines of the VDDHD structure 132 and the capacitor electrode 142 to manage parasitic capacitance therebetween. For example, where the lines of the VDDHD structure 132 and the capacitor electrode 142 extend substantially parallel to the lines of the word line 122 or VSS line 502, the separation can aid in the management of parasitics or other signal interference. However, such a routing (e.g., as depicted) is not intended to limit the present disclosure. Indeed, the present disclosure contemplates the use of any of various capacitor implementations, such as transistor gate capacitors.

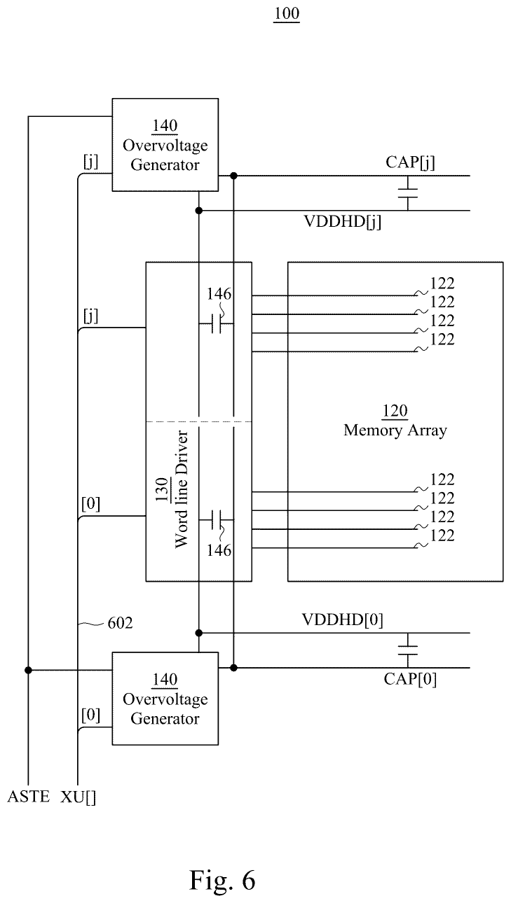

FIG. 6 illustrates another block diagram of a memory circuit 100, in accordance with some embodiments. The memory circuit 100 includes a memory array 120 having a first set of memory cells 302 configured to receive a voltage in excess of VDD from a first overvoltage generator 140 (e.g., the memory cells connected to the upper four word lines 122). Each upper word line 122 can connect to multiple memory cells 302 (e.g., tens or hundreds of memory cells 302). The memory array 120 also includes a second set of memory cells 302 configured to receive a voltage in excess of VDD from a second overvoltage generator 140 (e.g., the memory cells 302 connected to the lower four word lines 122). Each lower word line 122 can connect to multiple memory cells 302 (e.g., tens or hundreds of memory cells 302). For example, each of the upper and lower word lines 122 can connect to a same number of cells, equal to a number of rows of the memory array 120.

The inclusion of the multiple OVG 140 can decrease a portion of the vertical extension of the VDDHD structure 132 and the capacitor electrode structure 142 which is charged and discharged, which may reduce power use according to energy losses associated with charge/discharge cycles of the capacitor.

The sets of memory cells can be divided according to an address line 602. Accordingly, a same address line 602 can be used to control selection of each of the word line driver 130 and the overvoltage generator 140. For example, a first set of memory cells of the memory array 120 (e.g., the upper half) may be addressable according to a first state of an address line 602. The first state can include an uppermost but for addressing the memory array 120, so that, for an array having eight word lines 122, a word line address of [0XX] can correspond to the upper first four word lines 122, corresponding to the first OVG 140. A word line address of [1XX] can correspond to the lower first four word lines 122, corresponding to the second OVG 140. Accordingly, the second set of memory cells may be referred to as addressable according to a second state of the address line 602, opposite from the first state. Although, in the preceding example, the opposite state can correspond to a single bit of an address particular to a word line 122, the opposite state can refer to other addressing schemas for addressing respective memory cells of a memory array 120. For example, in some embodiments, the word line drivers 130 may be separated according to multiple bits of an address or an even/odd split. Moreover, in some embodiments, additional (e.g., four) overvoltage generators 140 may be used to assert the various word lines 122.

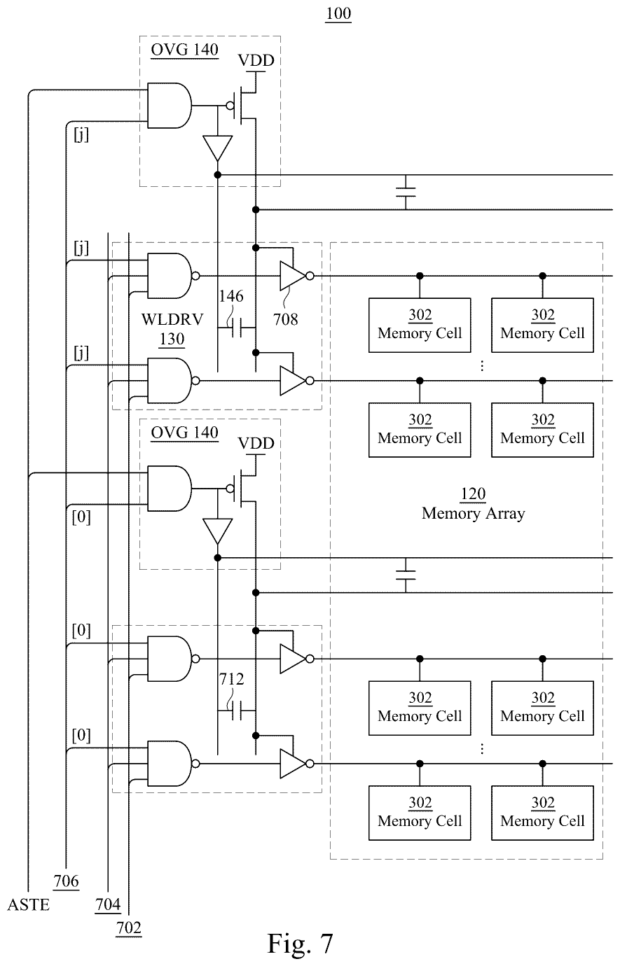

FIG. 7 illustrates a schematic diagram of a portion of the memory circuit 100 of FIG. 6, in accordance with some embodiments. In further detail, each word line 122 is shown as driven by an output 708 of the word line driver 130. The outputs 708 are activated based on addressable inputs (address bits of an address line). For example, the first address input 702 and second address input 704 can address a word line 122 within a portion of the memory array 120 (e.g., an upper or lower portion). A third, uppermost address input 706 can select between the upper and lower portion of the memory array 120, corresponding to the first and second set of memory cells discussed above, respectively. The third, uppermost address input 706 can further operate as a select line for the first OVG 140 and the second OVG 140. Particularly, the address line can be ANDed with an assist enable line (ASTE) of an assist circuit.

Some memory cells 302, such as the uppermost two cells, are coupled with a word line 122 (e.g., the uppermost word line 122 to continue the example). The word line driver 130 can selectively couple with the word line 122 to assert the word line 122 to a voltage, such as VDD. The upper OVG 140 can charge a capacitor 146 to a voltage exceeding the first voltage, such as to a VDDHD voltage. Other memory cells 302, such as the lowermost two cells, are coupled with another word line 122 (e.g., the lowermost word line 122 to continue the example). The word line driver 130 can selectively couple with the other word line 122 to assert the word line 122 to a voltage, such as VDD. The lower OVG 140 can charge another capacitor 712 to a voltage exceeding the first voltage, such as to a VDDHD voltage.

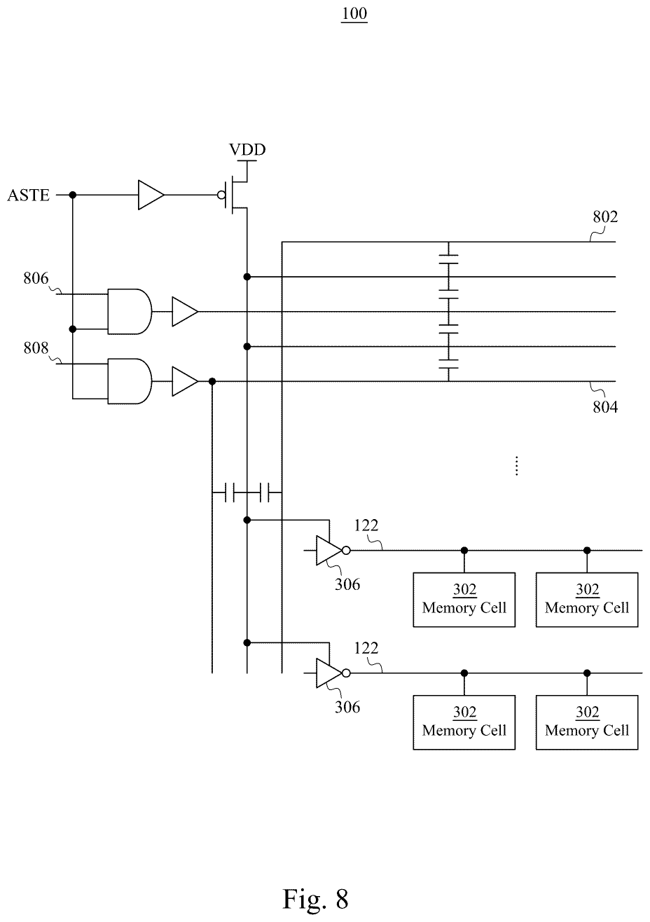

FIG. 8 illustrates a schematic diagram of a memory circuit 100, in accordance with some embodiments. A capacitor includes multiple electrodes couplable with the word lines 122 to assert the word lines 122 to a number of voltages corresponding to the number of electrodes. For example, the depicted example includes two such electrodes. A first capacitor electrode 802, can include any of the features of the electrode 142 of FIGS. 1 and 2. A second capacitor electrode 804, can contain similar features or can vary from the first capacitor electrode 802. In some embodiments, the circuit 100 can include additional capacitor electrodes. Each of the capacitor electrodes can be charged to a different voltage, or impart a different voltage upon a word line 122 coupled therewith. The first capacitor electrode 802 and second capacitor electrode 804 (and any further electrodes) can be store a similar or different charge.

A memory controller 110 can select, based on an operating condition, one or more of the electrodes. For example, the memory controller 110 can select the first capacitor electrode 802, second capacitor electrode 804, or both of the first capacitor electrode 802 and the second capacitor electrode 804. The memory controller 110 can select the electrodes 802, 804 according to a respective first select line 806 and second select line 808. According to the selection, the memory controller 110 can couple the selected electrode with the word line 122 to assert the word line 122 to a selected voltage. When more than one word line 122 is selected, the memory controller 110 can couple the selected lines with the word line 122 at a same time (e.g., to increase drive strength) or sequentially (e.g., to control slew). For example, the memory controller 110 can, according to a predefined timing or slew rate, couple the first capacitor electrode 802 with a word line 122, thereafter decouple the first capacitor electrode 802, and thereafter couple the second electrode 804 with the word line 122.

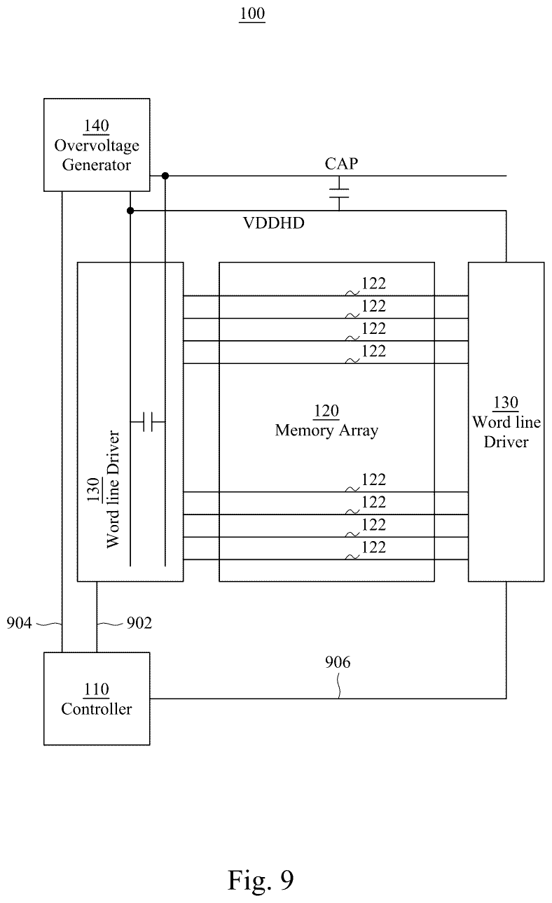

FIG. 9 illustrates a block diagram of a portion of a memory circuit 100, in accordance with some embodiments. The memory controller 110 can generate control signals to control the operation of the word line driver 130, another (far side) word line driver 130, and an OVG 140. The control signals can cause a storage or retrieval of data values from the various memory cells 302 of the memory array 120.

The word lines 122 are coupled with each of the word line drivers 130. Particularly, one end of the word lines 122 are coupled with a near end word line driver 130 and a second end of the word lines 122 are coupled with a far end word line driver 130 at an opposite end. The duplication of the word line drivers 130 may manage a voltage of the word line 122. For example, the duplication can manage an accumulation of resistive losses, or increase a total drive strength to increase a ramp rate slewed according to capacitance along the word line 122.

In some embodiments, the controller 110 can selectively operate the far side word line driver 130 according to an operating condition. For example, at low speed or low temperature operation, where voltage margin is not compressed to cause memory errors, a controller 110 may deactivate the far side word line driver 130 to lower power usage, as well as omit provision of control signals to cause an operation of the OVG 140. According to another operating condition (e.g., tight-timing, high-temperature operation), the controller 110 can activate the far side word line driver 130 and an OVG 140 (e.g., to charge multiple electrodes). During other operating conditions, the controller 110 can activate any subset of the systems described herein. For example, the controller 110 can include a look up table mapping operating conditions to activation of the various features provided herein.

Referring again to the control signals, such signals can include an address line 902 (e.g., including the first address input 702, second address input 704, and third address input 706). The control signals can further include the ASTE signal 904 and a control signal for the far side word line driver 130, which may be referred to as a boost enable or BSTE signal 906.

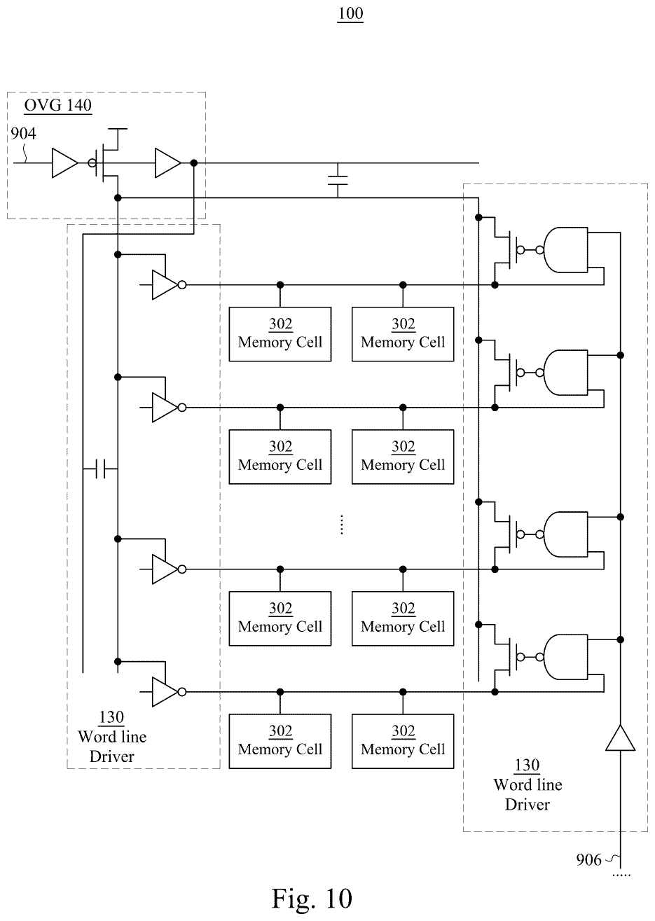

FIG. 10 illustrates a schematic diagram of a portion of the memory circuit 100 of FIG. 9, in accordance with some embodiments. In further detail, the far side word line driver 130 is depicted having inputs configured to receive the VDDHD structure 132, and output an assertion signal responsive to an input of the BSTE signal 906 and a detection of word line assertion (e.g., a logical AND thereof).

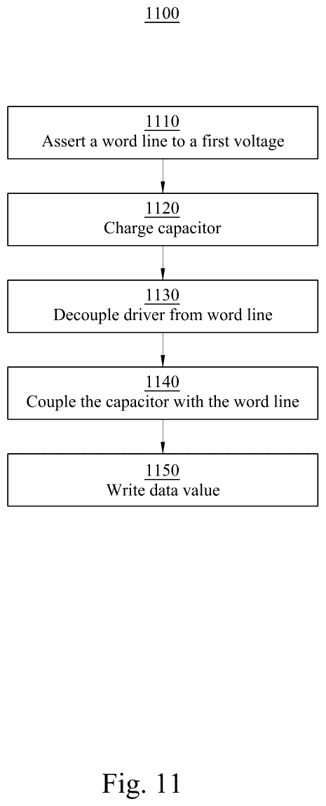

FIG. 11 illustrates a flow chart of a method 1100 for operation of a memory circuit 100, in accordance with some embodiments. For example, at least some of the operations (or steps) of the method 1100 can be used to store data in, or retrieve data from, the memory circuit 100 discussed above. Further, any of the operations can be controlled, managed, or timed by a memory controller 110. It is noted that the method 1100 is merely an example, and is not intended to limit the present disclosure. Accordingly, it should be understood that additional operations may be provided before, during, and/or after the method 1100 of FIG. 11, and that some other operations may only be briefly described herein.

The method 1100 includes, at operation 1110, driving a word line 122 to a first voltage by a word line driver 130. For example, the first voltage can be a VDD voltage of a memory system. In some instances, the first voltage can be an operative voltage (e.g., cause, in conjunction with actuated control lines, reading or writing of a data value from a memory cell). However, in some instances, the first voltage may result in a voltage margin less than a threshold, potentially leading to memory errors. In some embodiments, the controller 110 predicts (e.g., determines) a condition of a memory cell (e.g., via a temperature or voltage input associated with the memory cell, such as from a sensor or register disposed on a same die or package). The controller 110 can, based on the condition, proceed to operation 1120 or perform another operation or sub-operation such as selecting an electrode of a capacitor and coupling the selected electrode with the word line 122 to assert the word line 122 to the selected voltage.

The method 1100 includes, at operation 1120, charging, by a first overvoltage generator, a capacitor to a second voltage, greater than the first voltage. In some embodiments, the capacitor can include multiple electrodes coupled to the word line 122. For example, the electrode can include an electrode coupled to a reference voltage VSS, to which VDD is referred to. In some embodiments, the electrode coupled to the reference voltage can be referenced to another voltage, such as VDD, such that the voltage of the capacitor as charged will exceed VDD. The capacitor includes at least one electrode separate from the electrode charged to the reference voltage. For example, the at least one electrode can be spaced from the reference voltage according to a spacing in a metallization layer of a semiconductor device. Some capacitors can include multiple such electrodes (which may also be referred to as separate capacitors, without limiting effect). For example, each of a first, second, and third electrode can be charged to separate voltages. The capacitor is charged prior to operation 1140, but charging can otherwise be performed at various positions within a sequence relative to other operations provided herein.

The method 1100 includes, at operation 1130, decoupling the word line 122 from the word line driver 130. The decoupling can leave a line of the word line driver 130 (e.g., VDDHD) as a floating node. The floating node can float at or about a VDD voltage, exclusive of any leakage or other interactions with adjoining signals.

The method 1100 includes, at operation 1140, coupling the capacitor with the word line 122 to assert the word line 122 to a third voltage, greater than the first voltage. The coupling can include electrical coupling (e.g., via a switch of the OVG 140) or other coupling to cause the voltage of the word line 122 to rise above a VDD level.

The method 1100 includes, at operation 1150, writing, to a first memory cell coupled to the word line 122 at the third voltage, a data value. For example, the controller 110 can actuate other bit lines, select lines, and so forth to coincide with the elevated voltage of the overdriven word lines 122 to execute a memory operation of reading or writing a data value to the memory cell.

In one aspect of the present disclosure, a memory circuit is disclosed. The memory circuit includes memory cells commonly coupled to a word line. The memory circuit includes a word line driver selectively coupled to the word line and configured to assert the word line to a first voltage when coupled to the word line. The memory circuit includes an overvoltage generator to charge a capacitor. The memory circuit includes a memory controller. The memory controller is configured to couple the word line driver with the word line to assert the word line to the first voltage. The memory controller is configured to decouple the word line driver from the word line to maintain the word line at the first voltage. The memory controller is configured to couple the overvoltage generator with the capacitor to charge the capacitor to a voltage exceeding the first voltage. The memory controller is configured to couple the capacitor with the word line to assert the word line to the voltage in excess of the first voltage. The memory controller is configured to write a data value to one of the plurality of memory cells with the word line driven to the voltage in excess of the first voltage.

In another aspect of the present disclosure, a memory system is disclosed. The memory system includes memory cells commonly coupled to a word line. The memory system includes a first driver to assert the word line to a first voltage. The memory system includes a second driver to assert the word line to a second voltage, greater than the first voltage. The memory system includes a controller configured to activate one of the first driver or the second driver according to a time in a write cycle and an operating condition of the plurality of memory cells.

In yet another aspect of the present disclosure, a method for storing a data value is disclosed. The method includes driving a word line to a first voltage by a word line driver. The method includes charging, by a first overvoltage generator, a capacitor to a second voltage, greater than the first voltage. The method includes decoupling the word line from the word line driver. The method includes coupling the capacitor with the word line to assert the word line to a third voltage, greater than the first voltage. The method includes writing, to a first memory cell coupled to the word line at the third voltage, a data value.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a plurality of memory cells commonly coupled to a word line;
a word line driver selectively coupled to the word line and configured to assert the word line to a first voltage when coupled to the word line;
an overvoltage generator configured to charge a capacitor; and
a memory controller configured to:
couple the word line driver with the word line to assert the word line to the first voltage;
decouple the word line driver from the word line to maintain the word line at the first voltage;
couple the overvoltage generator with the capacitor to charge the capacitor to a voltage exceeding the first voltage;
couple the capacitor with the word line to assert the word line to the voltage in excess of the first voltage; and
write a data value to one of the plurality of memory cells with the word line driven to the voltage in excess of the first voltage.

2. The memory circuit of claim 1, wherein the memory circuit is configured to:
receive an indication of an operating condition comprising an operating temperature, operating voltage, or timing parameter;
select, based on the operating condition, the voltage exceeding the first voltage; and
couple the capacitor with the word line responsive to the selection of the voltage.

3. The memory circuit of claim 1, wherein the capacitor comprises a plurality of electrodes couplable with the word line to assert the word line to a plurality of voltages.

4. The memory circuit of claim 3, wherein the memory controller is configured to:
select, based on an operating condition of the memory circuit, a first of the plurality of electrodes; and
couple the first electrode with the word line.

5. The memory circuit of claim 3, wherein the memory controller is configured to, according to a predefined timing or slew rate:
couple a first electrode of the plurality of electrodes with the word line; and
couple a second electrode of the plurality of electrodes with the word line.

6. The memory circuit of claim 1, wherein the capacitor comprises a metal line disposed in a metallization layer of the memory circuit.

7. The memory circuit of claim 1, further comprising:
a second plurality of memory cells couplable with a second word line, the word line driver selectively coupled to the second word line and configured to assert the second word line to the first voltage; and
a second overvoltage generator to charge a second capacitor to the voltage exceeding the first voltage.

8. The memory circuit of claim 7, wherein the plurality of memory cells are addressable according to a first state of an address line and the second plurality of memory cells are addressable according to a second state of the address line, opposite from the first state.

9. The memory circuit of claim 1, wherein the word line is coupled to a second word line driver at a second end, opposite from a first end driven by the word line driver.

10. A system, comprising:
a plurality of memory cells commonly coupled to a word line;
a first driver configured to assert the word line to a first voltage when coupled to the word line;
a second driver configured to assert the word line to a second voltage, the second voltage greater than the first voltage; and
a controller configured to activate one of the first driver or the second driver according to a time in a write cycle and an operating condition of the plurality of memory cells.

11. The system of claim 10, wherein the operating condition comprises an operating temperature, operating voltage, or timing parameter of a semiconductor device including the plurality of memory cells and the controller.

12. The system of claim 11, wherein the timing parameter is a configurable setting accessible to the controller via a timing register.

13. The system of claim 10, wherein, to assert the word line to the second voltage, the controller is configured to:
couple the first driver with the word line and activate the first driver to assert the word line to the first voltage;
decouple the first driver from the word line;
charge a capacitor to the second voltage; and
couple an electrode of the capacitor with the word line via the second driver.

14. The system of claim 10, wherein:
a capacitor includes a plurality of electrodes couplable with the word line; and
the controller is configured to select an electrode from the plurality of electrodes based on the operating condition of the plurality of memory cells, and assert the word line from the capacitor via the second driver.

15. A method for storing a data value, comprising:
driving a word line to a first voltage by a word line driver;
charging, by a first overvoltage generator, a capacitor to a second voltage, greater than the first voltage;
decoupling the word line from the word line driver;
coupling the capacitor with the word line to assert the word line to a third voltage, greater than the first voltage; and
writing, to a first memory cell coupled to the word line at the third voltage, a data value.

16. The method of claim 15, wherein the capacitor comprises a metal line disposed in a metallization layer vertically spaced from a transistor of the first memory cell.

17. The method of claim 15, wherein the method comprises:
charging, by a second overvoltage generator, a second capacitor to the second voltage;
coupling the second capacitor with a second word line to assert the second word line to the third voltage; and
writing, to a second memory cell coupled to the word line at the third voltage, a second data value, wherein:
the first memory cell and the second memory cell are cells of a same array;
the word line is coupled to a first plurality of memory cells of the array comprising the first memory cell, and connected to a first address line and not to a second address line; and
the second word line is coupled to a second plurality of memory cells of the array, the second plurality of memory cells comprising the second memory cell and connected to the second address line and not to the first address line.

18. The method of claim 15, wherein the capacitor comprises:
a first electrode at the third voltage; and
a second electrode at a fourth voltage, higher than the third voltage.

19. The method of claim 18, further comprising:
determining a condition of the first memory cell corresponding to a voltage, temperature, or configurable timing parameter;
selecting, based on the condition, the third voltage rather than the fourth voltage; and
coupling, responsive to the selection, the first electrode of the capacitor to the word line to assert the word line to the third voltage.

20. The method of claim 15, comprising:
driving the word line, by a second word line driver at a second end of the word line, opposite from a first end of the word line driven by the word line driver.
